(19) United States
(12) Patent Application Publication
(10) Pub. No.: US 2022/0006052 A1
(43) Pub. Date: Jan. 6, 2022

(54) DISPLAY PANEL AND METHOD FOR FABRICATING THE SAME

(71) Applicants: Chengdu BOE Optoelectronics Technology Co., Ltd., Dhengdu, Sichuan (CN); BOE TECHNOLOGY GROUP CO., LTD., Beijing (CN)

(72) Inventor: Xing HUANG, Beijing (CN)

(21) Appl. No.: 17/280,884

(22) PCT Filed: May 9, 2020
(86) PCT No.: PCT/CN2020/089305

§ 371 Date: Mar. 27, 2021

(30) Foreign Application Priority Data
May 13, 2019 (CN) 201910393914.1

(51) Int. Cl. H01L 51/52; H01L 27/32; H01L 51/56

(52) U.S. Cl. CPC H01L 51/5253; H01L 51/5284; H01L 2227/323; H01L 27/3246; H01L 51/56; H01L 51/5271

(57) ABSTRACT

The present application provides a display panel and a method for fabricating the display panel. The display panel includes a display substrate; and an encapsulation layer for encapsulating the display substrate. The display substrate includes a base substrate and a pixel layer on the base substrate, and the pixel layer includes a plurality of display elements spaced apart from each other by a spacer region. The encapsulation layer includes a first encapsulation layer on a side of the pixel layer away from the base substrate and including a light-shielding and light-reflecting portion and a light-transmitting portion. An orthographic projection of the spacer region between adjacent display elements covers an orthographic projection of the light-shielding and light-reflecting portion on the base substrate, and an orthographic projection of the light-transmitting portion on the base substrate covers an orthographic projection of the display element on the base substrate.

### CROSS REFERENCE TO RELATED APPLICATION

The present application claims priority to Chinese patent application No. 201910393914.1, filed on May 13, 2019 to China National Intellectual Property Administration, the present disclosure of which is incorporated herein by reference.

### TECHNICAL FIELD

The present disclosure relates to the field of display devices, and in particular, to a display panel and a method for fabricating the display panel.

### BACKGROUND

In a top-emission type organic light emitting diode display panel with higher resolution, different pixel units are not shielded from each other, so that the phenomenon that light emitted by the organic light emitting diode in one pixel unit is irradiated into other pixel units easily occurs, color mixing is thus caused, and the display effect is reduced.

Therefore, how to avoid color mixing between different pixel units in the organic light emitting diode display panel is an urgent technical problem to be solved in the art.

### SUMMARY

In an aspect, the present disclosure provides a display panel, including: a display substrate; and an encapsulation layer for encapsulating the display substrate. The display substrate includes a base substrate and a pixel layer on the base substrate, and the pixel layer includes a plurality of display elements spaced apart from each other by a spacer region. The encapsulation layer includes a first encapsulation layer on a side of the pixel layer away from the base substrate and including a light-shielding and light-reflecting portion and a light-transmitting portion, an orthographic projection of the spacer region between a display element and an adjacent display element of plurality of display elements covers an orthographic projection of the light-shielding and light-reflecting portion on the base substrate, and an orthographic projection of the light-transmitting portion on the base substrate covers an orthographic projection of the display element on the base substrate. The light-transmitting portion is made of a transparent material, and a surface of the light-shielding and light-reflecting portion facing the light-transmitting portion is capable of reflecting light.

In an embodiment, the pixel layer further includes a pixel definition layer including a plurality of pixel openings, at least a portion of the display element is disposed in a respective one of the plurality of pixel openings, and a portion of the pixel definition layer other than the plurality of pixel openings serve as the spacer region.

In an embodiment, the light light-shielding and light-reflecting portion includes a light-reflecting layer and an opaque light-shielding body, the light-shielding body is disposed on a side of the pixel layer away from the base substrate, and the light-reflecting layer is disposed at least on a surface of the light-shielding body facing the light-transmitting portion.

In an embodiment, the light-reflecting layer is made of a metal material having a reflectivity of not less than 90% to visible light.

In an embodiment, the light-reflecting layer includes at least one of silver, aluminum and copper.

In an embodiment, each of the plurality of display elements includes a second electrode, a light emitting layer and a first electrode, which are disposed along a direction away from the base substrate. Second electrodes of the plurality of display elements are spaced apart from each other by the spacer region, light emitting layers of the plurality of display elements are spaced apart from each other by the spacer region, and first electrodes of the plurality of display elements are formed as a single piece. The light-shielding body is made of a conductive opaque material, and is electrically coupled to the first electrode of the display element through the light-reflecting layer.

In an embodiment, an angle between the surface of the light-shielding and light-reflecting portion facing the light-transmitting portion and a surface of the pixel layer away from the base substrate is between 70° and 80°.

In an embodiment, the encapsulation layer further includes a second encapsulation layer on a side of the first encapsulation layer away from the pixel layer.

In an embodiment, the light-shielding body includes a polyimide material to which a black dye is added.

In an embodiment, the black dye includes carbon black.

In an embodiment, the light-shielding body includes an organic material and metal particles filled in the organic material, such that the light-shielding body has conductivity.

In another aspect, the present disclosure provides a method for fabricating a display panel, including: providing a base substrate and forming a pixel layer on the base substrate to obtain a display substrate, the pixel layer including a plurality of display elements spaced apart from each other by a spacer region; and encapsulating the display substrate by using an encapsulation layer, which includes forming a first encapsulation layer on a side of the pixel definition layer away from the base substrate and including a light-shielding and light-reflecting portion and a light-transmitting portion. An orthographic projection of the spacer region between a display element and an adjacent display element of plurality of display elements covers an orthographic projection of the light-shielding and light-reflecting portion on the base substrate, and an orthographic projection of the light-transmitting portion on the base substrate covers an orthographic projection of the display element on the base substrate. The light-transmitting portion is made of a transparent material, and a surface of the light-shielding and light-reflecting portion facing the light-transmitting portion is capable of reflecting light.

In an embodiment, the step of forming the pixel layer on the base substrate includes: forming a pattern including a plurality of anodes; forming a pixel definition layer including a plurality of pixel openings, an orthographic projection of each anode of the plurality of anodes on the base substrate at least partially overlaps an orthographic projection of a respective one of the plurality of pixel openings on the base substrate; forming a light emitting layer in each of the plurality of pixel openings; and forming a cathode layer so that a respective one of the plurality of display elements is formed at each of the plurality of pixel openings, wherein the light-shielding and light-reflecting portion is disposed on a portion of the pixel definition layer other than the plurality of pixel openings.

In an embodiment, an angle between the surface of the light-shielding and light-reflecting portion facing the light-transmitting portion and a surface of the pixel layer away from the base substrate is between 70° and 80°.

In an embodiment, the step of forming the first encapsulation layer includes: forming an initial encapsulation layer by using a transparent material, wherein a part of the initial encapsulation layer corresponding to a spacer region between two adjacent display elements is formed as a recess, and a part of the initial encapsulation layer corresponding to the display element is formed as the light-transmitting portion; disposing a light-reflecting layer on an inner surface of the recess; and disposing a light-shielding body on the light-reflecting layer, wherein the light-reflecting layer and the light-shielding body form the light-shielding and light-emitting portion.

In an embodiment, each of the plurality of display elements includes a respective one of the plurality of anodes, the light emitting layer and the cathode layer, which are disposed along a direction away from the base substrate. A plurality of anodes of the plurality of display elements are spaced apart from each other by the spacer region, light emitting layers of the plurality of display elements are spaced apart from each other by the spacer region, and cathode layers of the plurality of display elements are formed as a single piece. The light-shielding body is made of a conductive opaque material, and is electrically coupled to the cathode layer of the display element through the light-reflecting layer.

### BRIEF DESCRIPTION OF THE DRAWINGS

The accompanying drawings, which are included to provide a further understanding of the present disclosure and are incorporated in and constitute a part of this specification, illustrate embodiments of the present disclosure and together with the description serve to explain the present disclosure, but do not constitute a limitation of the present disclosure. In the drawings:

FIG. 1 is a schematic diagram of a display panel according to the present disclosure; and

FIG. 2 is a flowchart showing a method for fabricating a display panel according to the present disclosure.

### DETAILED DESCRIPTION

Next, the specific embodiments of the present disclosure will be described in detail with reference to the accompanying drawings. It should be understood that the specific embodiments described herein are given by way of illustration and explanation only, not limitation.

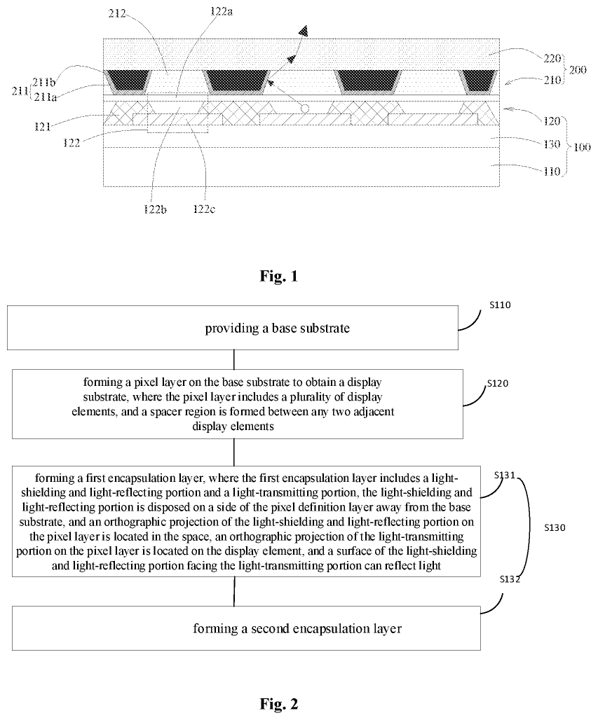

As an aspect of the present disclosure, there is provided a display panel, and as shown in FIG. 1, the display panel includes a display substrate 100 and an encapsulation layer 200 for encapsulating the display substrate 100. The display substrate 100 includes a base substrate 110 and a pixel layer 120 formed on the base substrate 110. The pixel layer 120 includes a plurality of display elements 122, and a spacer region is formed between two adjacent display elements 122. In an embodiment, the encapsulation layer 200 includes a first encapsulation layer 210 on a side of the pixel layer 120 away from the base substrate 110 and including a light-shielding and light-reflecting portion 211 and a light-transmitting portion 212. An orthographic projection of the light-shielding and light-reflecting portion 211 on the pixel layer 120 is in the spacer region between the display elements 122, and an orthographic projection of the light-transmitting portion 212 on the pixel layer 120 is on the display element 122. In an embodiment, the orthographic projection of the light-transmitting portion 212 on the base substrate 110 covers the orthographic projection of the display element 122 on the base substrate 110. For example, the orthographic projection of the light-transmitting portion 212 on the base substrate 110 completely overlaps with the orthographic projection of the display element 122 on the base substrate 110. For another example, an area of the orthographic projection of the light-transmitting portion 212 on the base substrate 110 is larger than an area of the orthographic projection of the display element 122 on the base substrate 110. In an embodiment, an orthographic projection of the spacer region on the base substrate 110 covers an orthographic projection of the light-shielding and light-reflecting portion 211 on the base substrate 110. For example, the orthographic projection of the spacer region on the base substrate 110 completely overlaps with the orthographic projection of the light-shielding and light-reflecting portion 211 on the base substrate 110. For another example, an area of the orthographic projection of the spacer region on the base substrate 110 is larger than an area of the orthographic projection of the light-shielding and light-reflecting portion 211 on the base substrate 110. The surface of the light-shielding and light-reflecting portion 211 facing the light-transmitting portion 212 is configured to reflect light. For example, the surface of the light-shielding and light-reflecting portion 211 includes a highly reflective material.

It should be noted that the pixel layer 120 includes a plurality of pixel units, each pixel unit includes one display element 122, the first encapsulation layer 210 is located on a light-emitting side of the display element 122, and the display element 122 emits light toward the first encapsulation layer 210. A part of light emitted from the display element 122 directly exits through the light-transmitting portion 212, and another part of light emitted from the display element 122 is irradiated on the surface of the light-shielding and light-reflecting portion 211 facing the light-transmitting portion 212 (for convenience of description, the surface of the light-shielding and light-reflecting portion 211 facing the light-transmitting portion 212 is hereinafter referred to as a light-reflecting surface of the light-shielding and light-reflecting portion 211), and is reflected into the light-transmitting portion 212 by the light-reflecting surface of the light-shielding and light-reflecting portion 211, so that light can be prevented from entering adjacent pixel units, a phenomenon of color mixing of different pixel units during light emission can be avoided, and a display effect of the display panel can be improved.

The phenomenon of color mixing of different pixel units during light emission is avoided, so that the display effect of the display panel can be improved, the light emitting range of the display panel can be reduced, and the anti-peep performance of the display panel is improved.

In the present disclosure, the specific type of the display panel is not particularly limited. For example, the display panel may be a liquid crystal display panel or a light emitting diode display panel. When the display panel is a liquid crystal display panel, the display element 122 includes a pixel electrode and a common electrode, but in this case, the display element does not actively emit light, but transmits light emitted from the backlight to the light-emitting surface. That is, the above “light emitted from the display element” is actually “light emitted through the display element”.

When the display element 122 is a light emitting diode, the display element can actively emit light, and the above “light emitted from the display element” is light emitted by the light emitting diode.

In the present disclosure, there is no particular requirement on how to space adjacent two display elements 122 apart. For example, the display element 122 may be a light emitting diode, the pixel layer 120 may further include a pixel definition layer 121 including a plurality of pixel openings in which at least a portion of the display element 122 is disposed, and a portion of the pixel definition layer 120 other than the pixel openings may serve as the spacer region. Accordingly, the light-shielding and light-reflecting portion 211 is provided in the portion (i.e., the spacer region as described above) of the pixel definition layer 121 other than the pixel openings. In an embodiment, an orthographic projection of the portion of the pixel definition layer 120 other than the pixel openings on the base substrate 110 covers (e.g., completely overlaps) an orthographic projection of the light-shielding and light-reflecting portion 211 on the base substrate 110, and an orthographic projection of the light-transmitting portion 212 on the base substrate 110 covers (e.g., completely overlaps) an orthographic projection of the pixel opening on the base substrate. It is to be noted that, in order to realize display of different colors, every three or four display elements on the display panel may be set as one pixel unit group, and in the same pixel unit group, the colors of light emitted by the display elements in adjacent two pixel openings are different.

In general, the pixel definition layer 121 may be formed using an organic material. The display element 122 may be an organic light emitting diode or an inorganic quantum-dot light emitting diode.

The display substrate may further include a pixel circuit layer 130 disposed between the pixel layer 120 and the base substrate 110, and the pixel circuit layer 130 is configured to drive the display elements 122 to emit light. In an embodiment, the pixel circuit layer 130 may include a thin film transistor (TFT) array. In an embodiment, amorphous silicon (a-Si), Low Temperature Poly-Silicon (LTPS), an oxide semiconductor, a carbon nanotube, graphene, or the like, is used as an active layer in the TFT, which is directly connected to a second electrode 122c. The display element as an OLED is controlled to emit light by signal input through the TFT array and a first electrode.

In the present disclosure, in order to further prevent the phenomenon of color mixing between two adjacent pixel units, in an embodiment, the light-shielding and light-reflecting portion 211 includes a light-reflecting layer 211a and an opaque light-shielding body 211b, the light-shielding body 211b is disposed on a side of the pixel layer 120 away from the base substrate 110, and the light-reflecting layer 211a is disposed at least on a surface of the light-shielding body 211b facing the light-transmitting portion 212.

Even if the light emitted from the display element 122 passes through the light-reflecting layer 211a, the light is absorbed by the light-shielding body 211b and does not enter the light-transmitting portion corresponding to the adjacent pixel unit. In an embodiment, the light-shielding body 211b may be black, so that the color of the light emitted from the display panel may be prevented from being affected.

For example, the light-shielding body 211b may be formed using a polyimide material to which a black dye (e.g., carbon black) is added.

In an embodiment, the light-reflecting layer 211a may be made of a metal material. For example, the light-reflecting layer 211a may be made of a metal material (e.g., at least one of metallic silver, metallic aluminum, and metallic copper) having a reflectivity of not less than 90% to visible light.

In an embodiment, the display element 122 includes a first electrode 122a, a light emitting layer 122b, and a second electrode 122c, and as shown in the figure, the second electrode 122c is formed on the pixel circuit layer 130, the light emitting layer 122b is disposed in the pixel opening, and first electrodes 122a of a plurality of display elements are formed as a whole electrode having an integral structure. The first electrode 122a may be made of a transparent electrode material (e.g., ITO).

In an embodiment, the display element further includes an electron transport layer and a hole transport layer located on opposite sides of the light emitting layer 122b in the thickness direction.

In the present disclosure, the light-reflecting layer 211a is made of a metal material, and may form a parallel structure with the whole first electrode 122a, where the resistance of the parallel structure is lower than that of the whole first electrode 122a, so that the IR drop during signal transmission can be reduced, and the uniformity of display can be improved.

In an embodiment, the light-shielding body 211b is made of a conductive opaque material, and is electrically coupled to the first electrode of the display element 122 through the light-reflecting layer 211a. The light-shielding body 211b also forms a parallel structure with the first electrode 122a, and the resistance of the parallel structure is lower than that of the whole first electrode 122a, so that the IR drop during signal transmission can be reduced, and the uniformity of display can be improved.

In an embodiment, the first electrode 122a may be a cathode and the second electrode 122c may be an anode.

In an embodiment, the second electrode 122c may be a metal with high reflection characteristics, such as nickel, gold, or platinum, or may be a metal/conductive oxide composite with high reflection characteristics, such as Indium Tin Oxide (ITO)/silver/ITO, and the resistivity of the second electrode 122c is lower than 5×10⁻⁴, which can provide a better conductive performance; meanwhile, the reflectivity of the second electrode 122c can reach over 85%, so that the light emitted from the display element 122 is reflected, and the light extraction efficiency is improved.

In an embodiment, the first electrode 122a may be a thin metal such as silver, aluminum, or a thin alloy such as magnesium-silver alloy, and has an optical transmittance of 85%, thereby improving the light extraction efficiency.

In order to realize the conductivity of the light-shielding body 211b, an organic material (for example, polyimide, a black matrix material, or another material having a low light transmittance) may be used as a base material, and the base material may be filled with metal particles. The metal particles may be made of a material having good conductivity, such as silver, copper, or aluminum.

In an embodiment, an orthographic projection of the light-shielding and light-reflecting portion 211 on the base substrate is in a grid structure, so that a parallel structure with the first electrode of the display element 122 can be ensured, the overall resistance can be better reduced, and the uniformity of display can be improved.

In addition to improving the uniformity of the display, another advantage of disposing the metal particles in the light-shielding body 211b is that the heat dissipation performance of the display panel can be improved, the display element can be prevented from being overheated, and the service life of the display element can be prolonged.

The surface of the first encapsulation layer 210 away from the pixel layer 120 should be a plane with high flatness, and the surface level of the light-shielding body 211b at different positions can be controlled to be consistent by means of ink-jet printing.

How to form the light-shielding body 211b and the light-reflecting layer 211a will be described in detail hereinafter, and will not be described herein.

In order to improve the light extraction efficiency of the display element, in an embodiment, an angle between the surface of the light-shielding and light-reflecting portion 211 facing the light-transmitting portion 212 and a surface of the pixel layer 120 away from the base substrate 110 is between 70° and 80°. Under the setting of the angle, the light emitted from the display element can be substantially and completely emitted through the light-transmitting portion 212 by the reflection action of the light-shielding and light-reflecting portion, thereby avoiding emitting light having different colors to adjacent pixel regions and avoiding the problem of color mixing.

Since the light-reflecting surface of the light-shielding and light-emitting portion 211 is an inclined surface, light emitted from the display element 212 is obliquely irradiated on the light-reflecting surface of the light-shielding and light-reflecting portion 211, reflected back to the light-transmitting portion 212, and emitted through the light-transmitting portion 212, thereby improving the light extraction efficiency of the display element 122. The solid arrows in FIG. 1 exemplarily show the light path along which the light emitted from the display element 212 is obliquely irradiated on the light reflecting surface of the light-shielding and light-reflecting portion and then emitted through the light-transmitting portion 212.

In the present disclosure, a specific material of the light-transmitting portion 212 is not particularly limited, and for example, the light-transmitting portion 212 may be made of a material having a transmittance of not less than 90% to visible light. In an embodiment, the light-transmitting portion 212 may be made of silicon nitride and/or silicon oxide. Of course, the present disclosure is not limited thereto, and the light-transmitting portion 212 may be made of a transparent organic material.

In order to further improve the effect of the encapsulation layer 200 in isolating moisture and oxygen, in an embodiment, the encapsulation layer 200 may further include a second encapsulation layer 220 disposed on a side of the first encapsulation layer 210 away from the pixel layer 120.

As a specific implementation, the second encapsulation layer 220 may be made of an inorganic material having a transmittance of not less than 90% to visible light or an organic-inorganic composite material having a transmittance of not less than 90% to visible light.

In the present disclosure, the specific structure of the base substrate 110 is not particularly limited, and for example, the base substrate 110 may be a rigid substrate and is made of glass. Of course, the present disclosure is not limited thereto, and the base substrate 110 may also be a flexible base substrate. For example, the base substrate 110 may include at least one of polyimide, polyethylene terephthalate, polyimide, polyetherimide, polyphenylene sulfide, and polyarylate. The type of base substrate may be determined according to the specific application of the display panel.

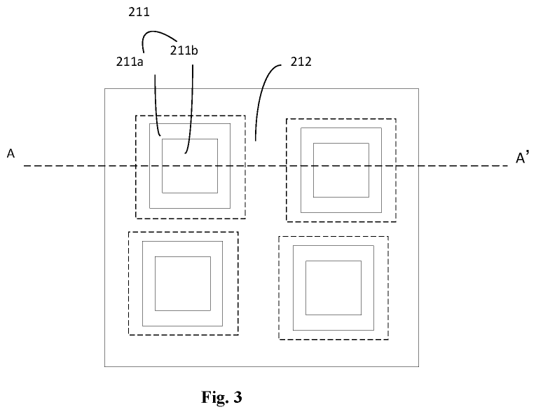

As another aspect of the present disclosure, there is provided a method for fabricating a display panel, and as shown in FIG. 2, the fabrication method includes steps S110 to S130.

In step S110, a base substrate is provided.

In step S120, a pixel layer is formed on the base substrate to obtain a display substrate, where the pixel layer includes a plurality of display elements, and a spacer region is formed between two adjacent display elements.

In step S130, the display substrate is encapsulated by using an encapsulation layer. The step S130 may include step S131.

In step S131, a first encapsulation layer is formed, where the first encapsulation layer includes a light-shielding and light-reflecting portion and a light-transmitting portion, the light-shielding and light-reflecting portion and the light-transmitting portion are both disposed on a side of the pixel definition layer away from the base substrate, and an orthographic projection of the light-shielding and light-reflecting portion on the pixel layer is located in a spacer region between the display elements, an orthographic projection of the light-transmitting portion on the pixel layer is located on the display element, and a surface of the light-shielding and light-reflecting portion facing the light-transmitting portion can reflect light.

The display panel provided by the present disclosure can be fabricated by using the fabrication method provided by the present disclosure, as described above, when the display panel emits light, a part of light emitted from the display element directly exits through the light-transmitting portion, and another part of light emitted from the display element is irradiated on the light-reflecting surface of the light-shielding light-reflecting portion and reflected into the light-transmitting portion by the light-reflecting surface of the light-shielding light-reflecting portion, so that light can be prevented from entering adjacent pixel units, a phenomenon of color mixing of different pixel units during light emission is avoided, and a display effect of the display panel is improved.

The phenomenon of color mixing of different pixel units during light emission is avoided, so that the display effect of the display panel can be improved, the light emitting range of the display panel can be reduced, and the anti-peep performance of the display panel is improved.

As an implementation, the pixel layer further includes a pixel definition layer, and the display element may be a light emitting diode, and accordingly, step S120 may include: forming a pattern including a plurality of anodes; forming a pixel definition layer including a plurality of pixel openings, each anode corresponding to a respective one of the pixel openings; forming a light emitting layer in the pixel openings; and forming a cathode layer so that each pixel opening is formed therein with one display element, where the light-shielding and light-reflecting portion is arranged on the pixel definition layer.

In order to improve the light extraction efficiency of the display element, in an embodiment, an angle between the surface of the light-shielding and light-reflecting portion facing the light-transmitting portion and the surface of the pixel layer away from the base substrate is between 70° and 80°.

In an embodiment, step S120 may further include forming a hole transport layer, an electron transport layer, and the like.

As described above, the light-transmitting portion may be made of a transparent material having a transmittance of not less than 90% to visible light.

Accordingly, step S131 may include: forming an initial encapsulation layer by using a transparent material, where the transmittance of the transparent material is not less than 90% to visible light, a part of the initial encapsulation layer corresponding to the spacer region between two adjacent display elements is formed as a recess, and a part of the initial encapsulation layer corresponding to the display element is formed as a light-transmitting portion; disposing a light-reflecting layer on an inner surface of the recess; and disposing a light-shielding body on the light-reflecting layer, where the light-reflecting layer and the light-shielding body form the light-shielding and light-emitting portion.

The transparent material may be an inorganic material or an organic material. When the transparent material is an inorganic material, the step of forming the initial encapsulation layer may include: depositing a transparent material layer with a preset thickness; and patterning the deposited transparent material layer to obtain the initial encapsulation layer.

When the transparent material is an organic material, the initial encapsulation layer may be formed directly by using an ink-jet printing technology.

The material of the light-shielding body may be polyimide with a dye added therein, and thus, the step of disposing the light-shielding body on the light-reflecting layer may include: forming a layer of dyed polyimide; and performing exposure and development on the layer of dyed polyimide to obtain the light-shielding body.

Of course, the light-shielding body may also be obtained by means of ink-jet printing. When the light-shielding body is formed by means of ink-jet printing, ink should have hydrophobicity, and by controlling the amount of the ink, the light-shielding body at different positions can be consistent in height, and finally the first encapsulation layer with a flat surface away from the pixel layer is obtained.

As an example, the transparent material forming the initial encapsulation layer may be composed of silicon oxide and/or silicon nitride. Therefore, the inorganic transparent material layer can be obtained by chemical vapor deposition or atomic layer deposition.

It is noted that the first encapsulation layer is formed on the cathode layer of the display element, and in order to avoid damage to the cathode, a lower deposition rate and a lower deposition temperature should be used when forming the inorganic transparent material layer by the chemical vapor deposition process.

As an implementation, the light-transmitting portion may be formed using an organic transparent material, and thus, step S131 may include: forming a plurality of light-transmitting portions by means of ink-jet printing; forming a light-reflecting layer at the spacer region between the light-transmitting portions; and forming a light-shielding body on the light-reflecting layer.

Similarly, in order to protect the cathode layer and the light emitting layer, the light-transmitting portion and the light-shielding body may be formed by printing ink having hydrophobicity.

As described above, the material of the light-reflecting layer may be made of a metal material having a reflectivity of not less than 90% to visible light. Further, the metal material may be selected from at least one of silver, copper and aluminum. The light-reflecting layer may be formed by physical vapor deposition such as sputtering, and the speed of physical vapor deposition should be reduced to avoid damage to the cathode.

Specifically, the patterning of the light-reflecting layer may be performed by using a photolithographic patterning process, which may includes: forming a metal material layer; forming a photoresist layer on the metal material layer; performing exposure and development on the photoresist layer to obtain a mask pattern, where the mask pattern is positioned at the spacer regions between the display elements; etching the metal material layer to obtain the light-reflecting layer; and removing the mask pattern.

The metal material layer may be etched by means of wet etching.

In addition to the photolithographic patterning process described above, laser induced thermal imaging techniques may also be used to pattern the metal material layer.

To further improve the moisture and oxygen isolation effect of the encapsulation layer, step S130 may further include step S132 performed after step S131.

In step S132, a second encapsulation layer is formed on a surface of the first encapsulation layer away from the display substrate. In an embodiment, the second encapsulation layer may be formed on the surface of the first encapsulation layer away from the display substrate by using an inorganic transparent material having a transmittance of not less than 90% to visible light or an organic-inorganic composite material having a transmittance of not less than 90% to visible light.

The material of the second encapsulation layer should have a relatively low moisture and oxygen permeability (e.g., <1.0×10⁻⁶ g/cm² per day) to achieve good encapsulation.

The second encapsulation layer may be formed using an inorganic material (e.g., silicon oxide and/or silicon nitride), or may be formed using an organic material.

Of course, the second encapsulation layer may also be made of a composite material of an inorganic material and an organic material.

As described above, the base substrate may be a rigid substrate such as a glass substrate or may be a flexible base substrate.

It will be understood that the above embodiments are merely exemplary embodiments employed to illustrate the principles of the present disclosure, and the present disclosure is not limited thereto. It will be apparent to those skilled in the art that various changes and modifications can be made therein without departing from the spirit and scope of the present disclosure, and these changes and modifications are to be considered within the scope of the present disclosure.

1. A display panel, comprising:
a display substrate; and
an encapsulation layer for encapsulating the display substrate,
wherein the display substrate comprises a base substrate and a pixel layer on the base substrate, the pixel layer comprising a plurality of display elements spaced apart from each other by a spacer region,
the encapsulation layer comprises a first encapsulation layer on a side of the pixel layer away from the base substrate and comprising a light-shielding and light-reflecting portion and a light-transmitting portion,
an orthographic projection of the spacer region between a display element and an adjacent display element of the plurality of display elements covers an orthographic projection of the light-shielding and light-reflecting portion on the base substrate, and an orthographic projection of the light-transmitting portion on the base substrate covers an orthographic projection of the display element on the base substrate,
the light-transmitting portion is made of a transparent material, and
a surface of the light-shielding and light-reflecting portion facing the light-transmitting portion is capable of reflecting light.

2. The display panel of claim 1, wherein the pixel layer further comprises a pixel definition layer comprising a plurality of pixel openings, and at least a portion of the display element is disposed in a respective one of the plurality of pixel openings, and a portion of the pixel definition layer other than the plurality of pixel openings serve as the spacer region.

3. The display panel of claim 1, wherein the light-shielding and light-reflecting portion comprises a light-reflecting layer and a light-shielding body which is opaque, the light-shielding body is disposed on a side of the pixel layer away from the base substrate, and the light-reflecting layer is disposed at least on a surface of the light-shielding body facing the light-transmitting portion.

4. The display panel of claim 3, wherein the light-reflecting layer is made of a metal material having a reflectivity of not less than 90% to visible light.

5. The display panel of claim 4, wherein the light-reflecting layer comprises at least one of silver, aluminum, and copper.

6. The display panel of claim 4, wherein
each of the plurality of display elements comprises a second electrode, a light emitting layer and a first electrode, which are disposed along a direction away from the base substrate,
second electrodes of the plurality of display elements are spaced apart from each other by the spacer region, light emitting layers of the plurality of display elements are spaced apart from each other by the spacer region, and first electrodes of the plurality of display elements are formed as a single piece, and
the light-shielding body is made of a conductive opaque material, and is electrically coupled to the first electrode of the display element through the light-reflecting layer.

7. The display panel of claim 1, wherein an angle between the surface of the light-shielding and light-reflecting portion facing the light-transmitting portion and a surface of the pixel layer away from the base substrate is between 70° and 80°.

8. The display panel of claim 1, wherein the encapsulation layer further comprises a second encapsulation layer on a side of the first encapsulation layer away from the pixel layer.

9. The display panel of claim 3, wherein the light-shielding body comprises a polyimide material to which a black dye is added.

10. The display panel of claim 9, wherein the black dye comprises carbon black.

11. The display panel of claim 6, wherein the light-shielding body comprises an organic material and metal particles filled in the organic material, such that the light-shielding body has conductivity.

12. A method for fabricating a display panel, comprising:
providing a base substrate and forming a pixel layer on the base substrate to obtain a display substrate, the pixel layer comprising a plurality of display elements spaced apart from each other by a spacer region; and
encapsulating the display substrate by using an encapsulation layer, which comprises forming a first encapsulation layer on a side of the pixel layer away from the base substrate and comprising a light-shielding and light-reflecting portion and a light-transmitting portion,
wherein an orthographic projection of the spacer region between a display element and an adjacent display element of the plurality of display elements covers an orthographic projection of the light-shielding and light-reflecting portion on the base substrate, and an orthographic projection of the light-transmitting portion on the base substrate covers an orthographic projection of the display element on the base substrate,
the light-transmitting portion is made of a transparent material, and
a surface of the light-shielding and light-reflecting portion facing the light-transmitting portion is capable of reflecting light.

13. The method of claim 12, wherein forming the pixel layer on the base substrate comprises:
forming a pattern comprising a plurality of anodes;
forming a pixel definition layer comprising a plurality of pixel openings, an orthographic projection of each anode of the plurality of anodes on the base substrate at least partially overlaps an orthographic projection of a respective one of the plurality of pixel openings on the base substrate;
forming a light emitting layer in each of the plurality of pixel openings; and
forming a cathode layer so that a respective one of the plurality of display elements is formed at each of the plurality of pixel openings, wherein the light-shielding and light-reflecting portion is disposed on a portion of the pixel definition layer other than the plurality of pixel openings.

14. The method of claim 12, wherein an angle between the surface of the light-shielding and light-reflecting portion facing the light-transmitting portion and a surface of the pixel layer away from the base substrate is between 70° and 80°.

15. The method of claim 12, wherein forming the first encapsulation layer comprises:
forming an initial encapsulation layer by using a transparent material, wherein a part of the initial encapsulation layer corresponding to the spacer region between two adjacent display elements is formed as a recess, and a part of the initial encapsulation layer corresponding to the display element is formed as the light-transmitting portion;
disposing a light-reflecting layer on an inner surface of the recess; and
disposing a light-shielding body on the light-reflecting layer, wherein the light-reflecting layer and the light-shielding body form the light-shielding and light-emitting portion.

16. The method of claim 15, wherein each of the plurality of display elements comprises a respective one of the plurality of anodes, the light emitting layer and the cathode layer, which are disposed along a direction away from the base substrate,
a plurality of anodes of the plurality of display elements are spaced apart from each other by the spacer region, light emitting layers of the plurality of display elements are spaced apart from each other by the spacer region, and cathode layers of the plurality of display elements are formed as a single piece, and
the light-shielding body is made of a conductive opaque material, and is electrically coupled to the cathode layer of the display element through the light-reflecting layer.

17. The method of claim 15, wherein the light-reflecting layer is made of a metal material having a reflectivity of not less than 90% to visible light.

18. The method of claim 17, wherein the light-reflecting layer comprises at least one of silver, aluminum, and copper.

19. The method of claim 15, wherein the light-shielding body comprises a polyimide material to which a black dye is added.

20. The method of claim 16, wherein the light-shielding body comprises an organic material and metal particles filled in the organic material, such that the light-shielding body has conductivity.
